(19) United States
(12) Patent Application Publication
(10) Pub. No.: US 2025/0034714 A1
(43) Pub. Date: Jan. 30, 2025

(54) REFLECTORS, SEMICONDUCTOR PROCESSING SYSTEMS HAVING REFLECTORS, AND METHODS OF DEPOSITING MATERIAL LAYERS IN SEMICONDUCTOR PROCESSING SYSTEMS USING REFLECTORS

(71) Applicant: ASM IP Holding B.V., Almere (NL)

(72) Inventors: Wentao Wang, Chandler, AZ (US); Peipei Gao, Chandler, AZ (US); Kishor Patil, Chandler, AZ (US); Aniket Chitale, Phoenix, AZ (US); Fan Gao, Chandler, AZ (US); Xing Lin, Chandler, AZ (US); Alexandros Demos, Scottsdale, AZ (US); Amir Kajbafvala, Chandler, AZ (US); Emesto Suarez, Scottsdale, AZ (US); Arun Murali, Tempe, AZ (US); Caleb Miskin, Mesa, AZ (US); Bubesh Babu Jotheeswaran, Gilbert, AZ (US)

(21) Appl. No.: 18/784,060

(22) Filed: Jul. 25, 2024

Related U.S. Application Data
(60) Provisional application No. 63/516,331, filed on Jul. 28, 2023.

(51) Int. Cl. C23C 16/46; C23C 16/06; C23C 16/458; C30B 25/10; C30B 25/12; C30B 29/52; H01L 21/02

(52) U.S. Cl. CPC C23C 16/46; C23C 16/06; C23C 16/4583; C30B 25/10; C30B 25/12; C30B 29/52; H01L 21/02532; H01L 21/0262

(57) ABSTRACT

A reflector includes a reflector body having a slotted surface, a planar surface, and an ellipsoidal surface. The planar surface is opposite the slotted surface and is separated from the slotted surface by a thickness of the reflector body. The ellipsoidal surface is offset from the planar surface, is opposite the slotted surface and separated from the slotted surface by the thickness of the reflector body and spans the slotted surface of the reflector body. The ellipsoidal surface defines an elliptical profile that is orthogonal relative to the planar surface to concentrate heat flux at a distal focus of the elliptical profile using electromagnetic radiation reflected by the ellipsoidal surface of the reflector body. Semiconductor processing systems and material layer deposition methods are also described.

### CROSS-REFERENCE TO RELATED APPLICATION(S)

This application claims the benefit of U.S. Provisional Application 63/516,331 filed on Jul. 28, 2023, the entire contents of which are incorporated herein by reference.

### FIELD OF INVENTION

The present disclosure generally relates to fabricating semiconductor devices. More particularly, the present disclosure relates to heating substrates during the deposition of material layers onto substrates used for the fabrication of semiconductor devices.

### BACKGROUND OF THE DISCLOSURE

Semiconductor devices, such as solar cells and integrated circuit semiconductor devices, are commonly fabricated by depositing material layers onto substrates. Material layer deposition is generally accomplished by supporting a substrate within a reaction chamber, heating the substrate to a desired material layer deposition temperature, and exposing the substrate to one more material layer precursors under environmental conditions selected to cause a material layer to deposit onto the substrate. Substrate heating may be accomplished using radiant heating arrangements, which typically use radiant heat sources like lamps supported outside of the reaction chamber in cooperation with a reflector to transmit radiant energy through walls of the reaction chamber to heat a substrate supported within the reaction chamber. Once the material layer reaches a desired thickness flow of the precursor and heating typically ceases and the substrate sent on for further processing, as appropriate for the semiconductor device being fabricated.

In some material layer deposition processes cross-substrate variation in the material layer deposited onto the substrate may influence properties of the material layer, potentially influencing performance of the semiconductor device or devices formed using the material layer. For example, cross-substrate variation in thickness of the material layer may induce corresponding cross-substrate variation in electrical properties of the material layer deposited onto the substrate, potentially influencing reliably of the semiconductor device or devices formed using the material layer. Cross-substrate variation in concentration of alloying constituents, such as germanium, as well as dopants, may also induce variation in electrical properties of the material layer deposited onto the substrate, also potentially influencing reliability of the semiconductor device or devices formed using substrate. In some deposition processes the material layer may roll up or roll down that the edge of the substrate, material layer or constituent concentration increasing or decreasing at the edge of the substrate in such processes, respectively.

Various countermeasures exist to limit cross-substrate material layer variation. For example, the substrate may be rotated relative to flow of material layer provided to the substrate to limit cross-substrate material layer variation. Mass flow rate of the precursor may be locally increased or decreased at the edge relative to the center of the substrate to compensate for variation within the material layer between the center and the edge of the substrate otherwise characteristic of the deposition process. And substrate heating may be varied between the center and the edge of the substrate, such as by changing radiant energy generated by radiant heat sources overlying the edge of the substrate relative to radiant heat sources lamps overlaying the center of the substrate, also compensating for variation within the material layer otherwise characteristic of the deposition process. While generally satisfactory, such techniques may be inadequate to compensate for cross-substrate material layer variation in some deposition processes.

Such systems and methods have generally been acceptable for their intended purpose. However, there remains a need for improved reflectors, semiconductor processing systems having reflectors, and methods of depositing material layers onto substrates in reaction chamber arrangements using reflectors. The present disclosure provides a solution to this need.

### SUMMARY OF THE DISCLOSURE

A reflector is provided. The reflector includes a reflector body having a slotted surface, a planar surface, and an ellipsoidal surface. The planar surface is opposite the slotted surface and is separated from the slotted surface by a thickness of the reflector body. The ellipsoidal surface is offset from the planar surface, is opposite the slotted surface and separated from the slotted surface by the thickness of the reflector body and spans the slotted surface of the reflector body. The ellipsoidal surface defines an elliptical profile that is orthogonal relative to the planar surface to concentrate heat flux at a distal focus of the elliptical profile using electromagnetic radiation reflected by the ellipsoidal surface of the reflector body.

In addition to one or more of the features described above, or as an alternative, further examples of the reflector may include that the ellipsoidal surface is a first ellipsoidal surface and that the reflector body has a second ellipsoidal surface. The second ellipsoidal surface may be separated from the slotted surface by the thickness of the reflector body. The second ellipsoidal surface may extend in parallel with the first ellipsoidal surface and be from the first ellipsoidal surface by the planar surface.

In addition to one or more of the features described above, or as an alternative, further examples of the reflector may include that the reflector body has a paraboloidal surface. The paraboloidal surface may define a parabolic profile. The parabolic profile may be orthogonal relative to the planar surface. The paraboloidal surface may extend in parallel with the ellipsoidal surface of the reflector body.

In addition to one or more of the features described above, or as an alternative, further examples of the reflector may include that the ellipsoidal surface separates the paraboloidal surface of the reflector body from the planar surface of the reflector body.

In addition to one or more of the features described above, or as an alternative, further examples of the reflector may include that the paraboloidal surface of the reflector body is separated from the ellipsoidal surface of the reflector body by the planar surface of the reflector body.

In addition to one or more of the features described above, or as an alternative, further examples of the reflector may include that the reflector body has a part-cylindrical surface. The part-cylindrical surface may define a part-circular profile. The part-circular profile may be orthogonal relative to the planar surface. The part-cylindrical surface may extend in parallel with the ellipsoidal surface of the reflector body.

In addition to one or more of the features described above, or as an alternative, further examples of the reflector may include that the part-cylindrical surface of the reflector body separates the ellipsoidal surface of the reflector body from the planar surface of the reflector body.

In addition to one or more of the features described above, or as an alternative, further examples of the reflector may include that the part-cylindrical surface of the reflector body is separated from the ellipsoidal surface by the planar surface of the reflector body.

In addition to one or more of the features described above, or as an alternative, further examples of the reflector may include that the reflector body has an inboard rib portion. The inboard rib portion may separate the planar surface of the reflector body from the ellipsoidal surface of the reflector body. The inboard rib portion may have a part-cylindrical surface. The part-cylindrical surface may define a part-circular profile that is orthogonal relative to the planar surface, and which faces the planar surface of the reflector body.

In addition to one or more of the features described above, or as an alternative, further examples of the reflector may include that the reflector body has an intermediate rib portion. The intermediate rib portion may be separated from the planar surface by the ellipsoidal surface of the reflector body. The intermediate rib portion may have a paraboloidal surface defining a parabolic profile. The parabolic profile may be orthogonal relative to the planar surface of the reflector body.

In addition to one or more of the features described above, or as an alternative, further examples of the reflector may include that the reflector body has an outboard rib portion. The outboard rib portion may be separated from the planar surface by the ellipsoidal surface of the reflector body. The outboard rib portion may have a paraboloidal surface and an edge surface, the paraboloidal surface defining a parabolic profile that is orthogonal relative to the planar surface, the edge surface orthogonal relative to the planar surface.

In addition to one or more of the features described above, or as an alternative, further examples of the reflector may include that the reflector body is formed from a bulk metallic material. A gold coating material may be conformally deposited onto both the planar surface and the ellipsoidal surface of the reflector body.

In addition to one or more of the features described above, or as an alternative, further examples of the reflector may include that the slotted surface defines a plurality of slots therein. The plurality of slots may extend in parallel with the ellipsoidal surface of the reflector body. The plurality of slots may fluidly couple the slotted surface with the planar surface and the ellipsoidal surface of the reflector body. The thickness of the reflector body may define therein a coolant channel. The coolant channel may extend between the slotted surface and the ellipsoidal surface of the reflector body.

In addition to one or more of the features described above, or as an alternative, further examples of the reflector may include that the reflector body may has a monolithic arrangement, or that the reflector body has a segmented arrangement including a first body segment and at least one second segment. The planar surface may be defined on the first body segment, the ellipsoidal surface may be defined on the at least one second body segment, and the second body segment abutting the first body segment at joint spanning the reflector body.

A semiconductor processing system is provided. The semiconductor processing system includes a chamber body formed from a transmissive material, a substrate support arranged within the chamber body, and a reflector as described above supported above the chamber body. A lamp array including two or more linear lamps is supported between the reflector and the chamber body, a first of the two or more linear lamps extends along a proximal focus of the elliptical profile defined by the ellipsoidal surface of the reflector body, and a second of the two or more linear lamps separate the planar surface of the reflector body from the chamber body and are parallel to the first of the two or more of linear lamps.

In addition to one or more of the features described above, or as an alternative, further examples of the semiconductor processing system may include that a distal focus of the elliptical profile defined by the ellipsoidal surface intersects a surface of a substrate seated on the substrate support.

In addition to one or more of the features described above, or as an alternative, further examples of the semiconductor processing system may include that the chamber body has a two or external ribs. The two or more external ribs may extend in parallel with the ellipsoidal surface of the reflector body. At least one of the of the two or more linear lamps may overlay one of the plurality of external ribs.

In addition to one or more of the features described above, or as an alternative, further examples of the semiconductor processing system may include that the chamber body has two or more external ribs. The external ribs may extend in parallel with the ellipsoidal surface. The first of the two or more linear lamps may be arranged between two of the external ribs.

In addition to one or more of the features described above, or as an alternative, further examples of the system may include that the substrate support is supported within the chamber body for rotation about a rotation axis. The proximal focus and the distal focus may be offset from the rotation axis by between about 135 millimeters and about 155 millimeters.

A material layer deposition method is provided. The material layer deposition method includes, at a semiconductor processing system including a reflector as described above, positioning a substrate at a distal focus of the elliptical profile of the reflector body, heating the substrate using electromagnetic radiation emitted by a lamp supported at a proximal focus of the elliptical profile of the reflector body, and further heating the substrate by reflecting electromagnetic radiation emitted in a direction opposite the substrate toward the distal focus using the ellipsoidal surface of the reflector body. A silicon-containing material layer is deposited onto the substrate using an epitaxial deposition technique, ellipsoidal surface concentrating heat flux at the distal focus of the elliptical profile using electromagnetic radiation reflected by the ellipsoidal surface, the heat flux concentrated at the distal focus of the elliptical profile limiting cross-substrate variation within the silicon-containing material layer deposited onto the substrate using the epitaxial deposition technique.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system including a reflector in accordance with the present disclosure, showing reflector communicating radiant energy generated by a lamp toward a substrate seated within the semiconductor processing system;

FIG. 2 is schematic view of the semiconductor processing system of FIG. 1 according to an example of the present disclosure, showing a silicon-containing precursor being provided to the substrate while the substrate is heated using reflected radiant energy;

FIG. 3 is a schematic view of the semiconductor processing system of FIG. 1 according to an example of the present disclosure, showing reflective surfaces of the reflector distributing radiant energy across the substrate according to shape of the reflective surfaces;

FIG. 4 is a perspective view of the reflector of FIG. 1 according to an example of the present disclosure, showing a slotted surface and opposite contoured surfaces of the reflector for distributing radiant energy across the substrate within the semiconductor processing system;

FIG. 5 is a top plan view of the reflector of FIG. 1 according to an example of the present disclosure, showing the slotted surface of the reflector and a plurality of slots defined within the slotted surface of the reflector;

FIG. 6 is a bottom plan view of the reflector of FIG. 1 according to an example of the present disclosure, showing the ellipsoidal surface separated from the planar surface by a part-cylindrical surface and the ellipsoidal surface separating a parabolic surface of the reflector from the planar surface of the reflector;

FIG. 7 is a side view of the reflector and a portion of the chamber arrangement of FIG. 1 according to an example of the disclosure, showing illumination distributions generated by electromagnetic radiation reflected by the ellipsoidal and planar surfaces of the reflector body;

FIG. 8 is a partial view of the chamber arrangement and reflector of FIG. 1 according to an example of the present disclosure, showing a paraboloidal surface and a paraboloidal surface illumination distribution generated by the paraboloidal surface using electromagnetic radiation reflected from the paraboloidal surface of the reflector;

FIG. 9 is a partial view of the chamber arrangement and reflector of FIG. 1 according to an example of the present disclosure, showing an ellipsoidal surface of the reflector and an ellipsoidal surface illumination distribution generated by the ellipsoidal surface;

FIGS. 10 and 11 are partials view of the chamber arrangement and reflector of FIG. 1 according to an example of the present disclosure, showing a part-cylindrical surface and a planar surface and associated part-cylindrical and planar surface illumination distributions, respectively;

FIG. 12 is graph of substrate edge temperature change responsive to power applied to a lamp overlying the edge of the substrate, showing greater temperature tunability in chamber arrangements including reflector having ellipsoidal surfaces overlying the substrate edge; and

FIG. 13 is a process flow diagram of a method of deposition a material layer onto a substrate according to an example of the present disclosure, showing operations of the method according to an illustrative and non-limiting example of the present disclosure.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

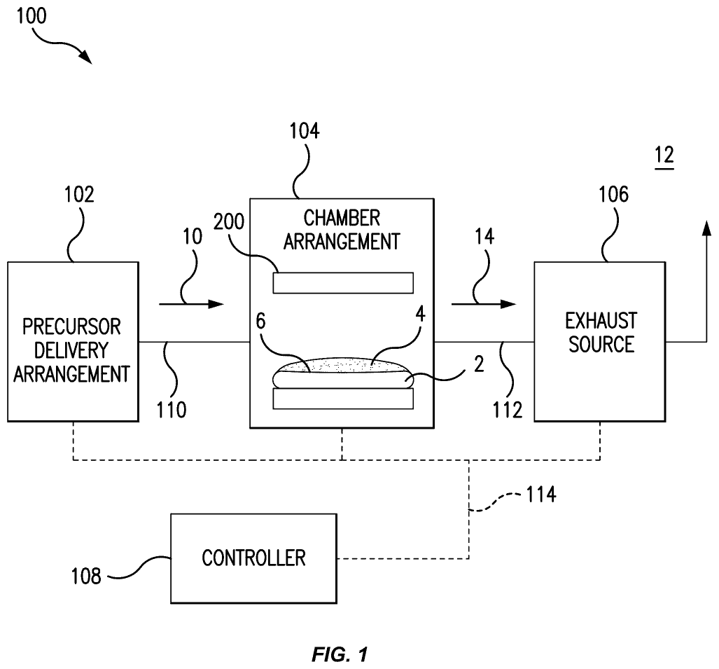

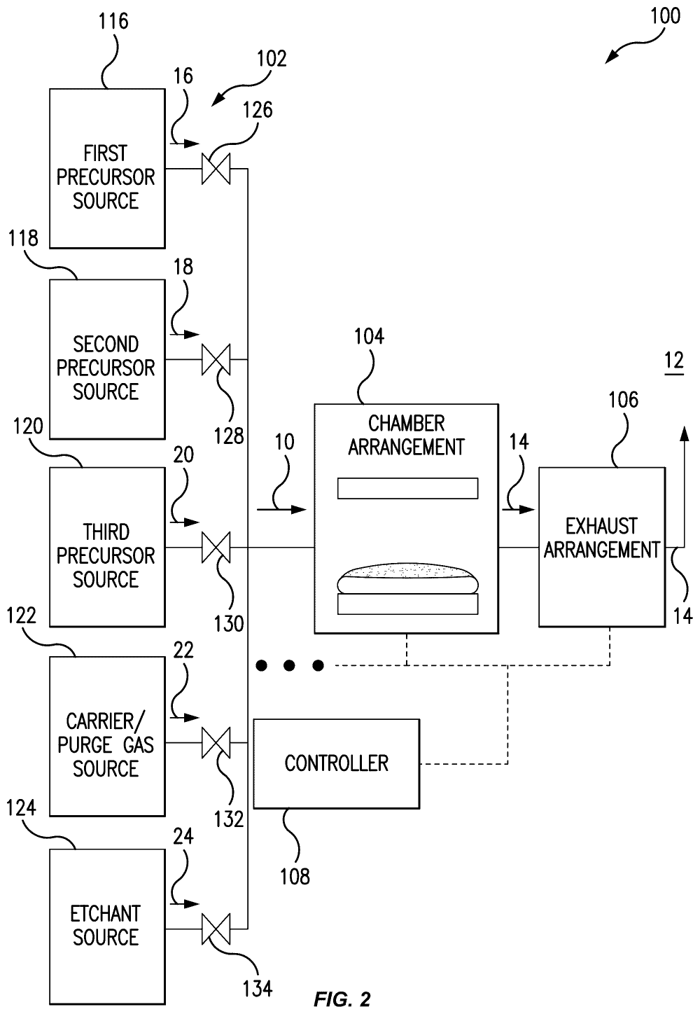

Reference will now be made to the drawings wherein like reference numerals identify similar structural features or aspects of the subject disclosure. For purposes of explanation and illustration, and not limitation, a partial view of a reflector included in a semiconductor processing system in accordance with the present disclosure is shown in FIG. 1 and is designated generally by reference character 200. Other examples of reflectors, semiconductor processing systems having reflectors, and methods of depositing material layers using reflectors in accordance with the present disclosure, or aspects thereof, are provided in FIGS. 2-13, as will be described. The systems and methods of the present disclosure may be used to deposit material layers onto substrates, such as during the fabrication of semiconductor devices like logic and memory semiconductor devices, through the present disclosure is not limited to a particular type of material layer to any particular type of semiconductor device in general.

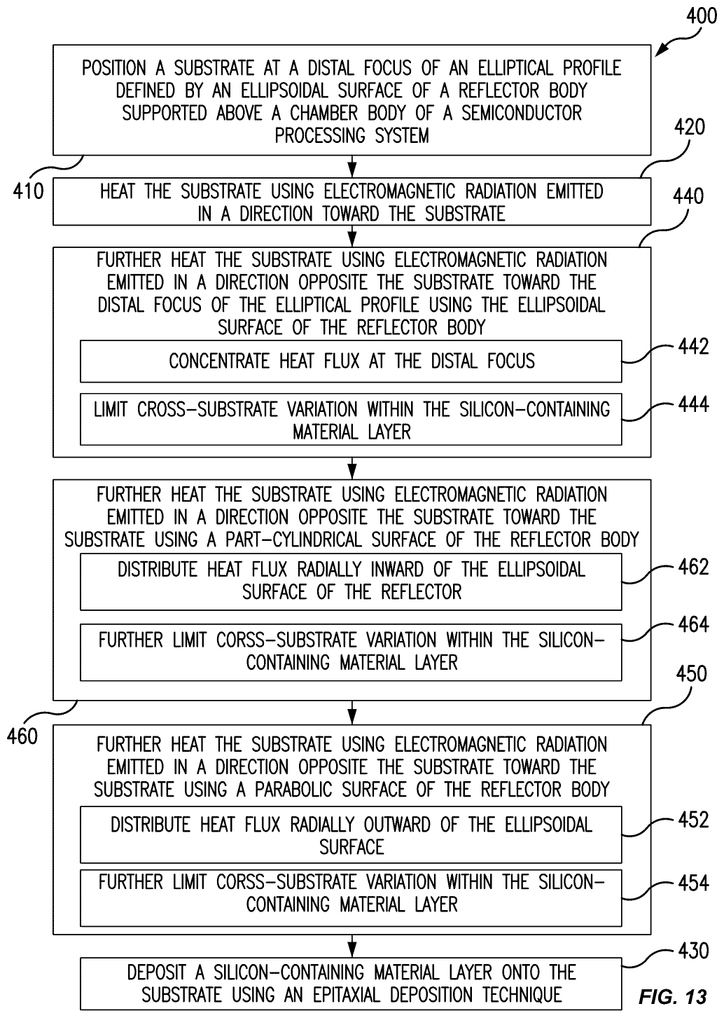

Referring to FIG. 1, a semiconductor processing system 100 is shown. The semiconductor processing system 100 includes a precursor delivery arrangement 102, a chamber arrangement 104 including the reflector 200, an exhaust source 106, and a controller 108. The precursor delivery arrangement 102 is connected to the chamber arrangement 104 by a precursor supply conduit 110 and is configured to provide a flow of one or more material layer precursor 10 to the chamber arrangement 104. The chamber arrangement 104 is configured to support a substrate 2 during deposition of a material layer 4 onto an upper surface 6 of the substrate 2 using the material layer precursor 10. The exhaust source 106 is connected to the chamber arrangement 104 by an exhaust conduit 112, fluidly couples the chamber arrangement 104 to an external environment 12 outside of the semiconductor processing system 100, and is configured to communicate a flow of a residual precursor and/or reaction products 14 issued by the chamber arrangement 104 to the external environment 12, for example, using a vacuum pump and/or an abatement apparatus. The controller 108 is operatively connected to the precursor delivery arrangement 102 and the chamber arrangement 104, for via wired or wireless link 114, the chamber arrangement 104, and is responsive to instructions recorded on a non-transitory machine-readable medium to deposit the material layer 4 onto the substrate 2 using a material layer deposition method 300 (shown in FIG. 13), as will be described.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers.

A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may an unpatterned, blanket-type substrate. As examples, substrates in the form of a powder may have applications for pharmaceutical manufacturing. A porous substrate may include one or more polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

With reference to FIG. 2, the precursor delivery arrangement 102 is shown according to an example of the present disclosure. In the illustrated example the precursor delivery arrangement 102 includes a first precursor source 116, a second precursor source 118, a third precursor source 120, a carrier/purge fluid source 122, and an etchant source 124. In certain examples, the precursor delivery arrangement 102 may be as shown and described in U.S. Pat. No. 11,053,591 to Ma et al., issued on Jul. 6, 2021, the contents of which are incorporated herein by reference in its entirety. Although shown and described herein as having a specific arrangement it is to be understood and appreciated that the precursor delivery arrangement 102 may have different arrangements in other examples of the present disclosure and remain within the scope of the present disclosure.

The first precursor source 116 is connected to the chamber arrangement 104 by a first precursor supply valve 126 and includes a silicon-containing material layer precursor 16. The first precursor source 116 is further configured to provide a flow of the silicon-containing material layer precursor 16 to the chamber arrangement 104 using the first precursor supply valve 126. The first precursor supply valve 126 is in turn operatively associated with the controller 108 and may include a mass flow controller (MFC) device. It is contemplated that the silicon-containing material layer precursor 16 may include one or more of a halogenated silicon-containing precursor and/or a non-halogenated silicon-containing precursor. Examples of suitable halogenated silicon-containing precursors include dichlorosilane (H₂SiCl₂) and trichlorosilane (HCl₃Si). Examples of suitable non-halogenated silicon-containing precursors include silane (SiH₄) and disilane (Si₂H₆).

The second precursor source 118 is similar to the first precursor source 116 is additionally connected to the chamber arrangement 104 by a second precursor supply valve 128. It is contemplated that the second precursor source 118 include a germanium-containing precursor 18 and that the second precursor source 118 be further configured to provide a flow of the germanium-containing precursor 18 to the chamber arrangement 104 using the second precursor supply valve 128. The second precursor supply valve 128 may be operatively associated with the controller 108, include an MFC device, and be configured to control mass flow rate of the germanium-containing precursor 18 to the chamber arrangement 104. Examples of suitable germanium-containing precursors include germane (GeH₄) and digermane (Ge₂H₆).

The third precursor source 120 is also similar to the first precursor source 116 and is additionally connected to the chamber arrangement 104 by a third precursor supply valve 130. It is contemplated that the third precursor source 120 include a dopant-containing precursor 20 and be configured to provide a flow of the dopant-containing precursor 20 to the chamber arrangement 104 using the third precursor supply valve 130. The third precursor supply valve 130 may in turn be operatively associated with the controller 108, include an MFC device, and be configured to control mass flow rate of the germanium-containing precursor 18 to the chamber arrangement 104. In certain examples the dopant-containing precursor 20 may include a p-type dopant, such as phosphorous (P) and/or arsenic (As). In accordance with certain examples, the dopant-containing precursor 20 may include an n-type dopant, such as boron (B) and/or gallium (Ga) and remain within the scope of the present disclosure.

The carrier/purge fluid source 122 is also similar to the first precursor source 116 and is additionally connected to the chamber arrangement 104 by a carrier/purge fluid supply valve 132. It is contemplated that the carrier/purge fluid source 122 include a carrier/purge fluid 22 and be configured to provide a flow of the carrier/purge fluid 22 to the chamber arrangement 104 using the carrier/purge fluid supply valve 132. The carrier/purge fluid supply valve 132 may in turn be operatively associated with the controller 108, include an MFC device, and be further configured to control mass flow rate of the carrier/purge fluid 22 to the chamber arrangement 104. In certain examples the carrier/purge fluid 22 may include an inert gas, such as nitrogen (N₂) gas. In accordance with certain examples, the carrier/purge fluid 22 may include a noble gas, such argon (Ar) and/or helium (He). It is also contemplated that the carrier/purge fluid 22 may include hydrogen (H₂) gas and remain within the scope of the present disclosure.

The etchant source 124 is also similar to the first precursor source 116 and is additionally connected to the chamber arrangement 104 by an etchant supply valve 134. It is contemplated that the etchant source 124 include an etchant fluid 24 and be configured to provide a flow of the etchant fluid 24 to the chamber arrangement 104 using the etchant supply valve 134. The etchant supply valve 134 may in turn be operatively associated with the controller 108, include an MFC device, and be configured to control mass flow rate of the etchant fluid 24 to the chamber arrangement 104. In certain examples, the etchant fluid 24 may include a halogen, such as chlorine (Cl) or fluorine (F). Examples of suitable etchant fluids include chlorine (Cl₂) gas, hydrochloric (HCl) acid, fluorine (F₂) gas, and hydrofluoric (HF) acid.

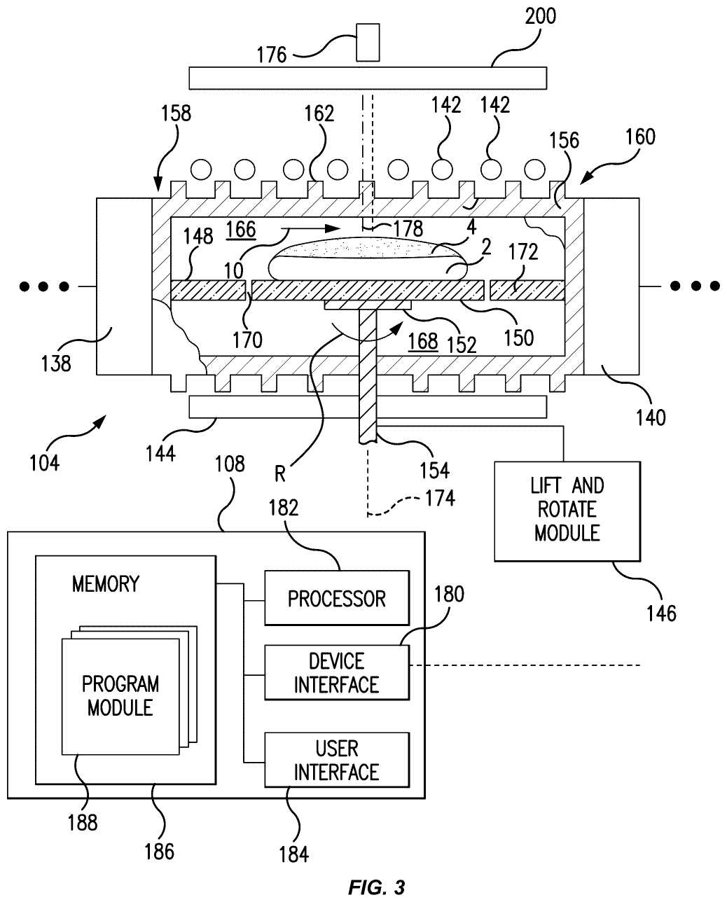

With reference to FIG. 3, the chamber arrangement 104 and the controller 108 are shown according to examples of the present disclosure. In the illustrate example the chamber arrangement 104 has a single-wafer crossflow arrangement and includes a chamber body 136, an injection flange 138, an exhaust flange 140. The chamber arrangement 104 also includes an upper heater element array 142, a lower heater element array 144, a lift and rotate module 146 a divider 148, a substrate support 150, a support member 152, and a shaft member 154. In certain examples the chamber arrangement 104 may be as shown and described in U.S. Patent Application Publication No. 2018/0363139 A1 to Rajavelu et al., filed on Apr. 25, 2018, the contents of which are incorporated herein by reference in their entirety. Although shown and described herein as having a specific arrangement herein, it is to be understood and appreciated that the chamber arrangement 104 may have different arrangements in other examples of the present disclosure (e.g., include additional elements and/or exclude certain elements shown and described herein) and remain within the scope of the present disclosure.

The chamber body 136 is formed from a transparent material 156, has an injection end 158 and a longitudinally opposite exhaust end 160, and has a plurality of exterior ribs 162 extending laterally about an exterior of the chamber body 136 and longitudinally spaced apart from one another between the injection end 158 and the exhaust end 160 of the chamber body 136. The injection flange 138 abuts the injection end 158 of the chamber body 136 and couples the precursor delivery arrangement 102 (shown in FIG. 1) to the chamber body 136. The exhaust flange 140 abuts the exhaust end 160 of the chamber body 136, is fluidly coupled to the injection flange 138 by an interior 164 of the chamber body 136 and couples the chamber body 136 to the exhaust source 106 (shown in FIG. 1). It is contemplated that the divider 148 be fixed within the interior 164 of the chamber body 136 and that the divider 148 divide the interior 164 of the chamber body 136 into an upper chamber 166 and a lower chamber 168. It is also contemplated that the divider 148 have a divider aperture 170 extending therethrough, and that the divider 148 be formed from an opaque material 172. In certain examples, the transparent material 156 forming the chamber body 136 may be transparent to electromagnetic radiation within an infrared waveband, such as quartz or sapphire. In accordance with certain examples, the opaque material 172 forming the divider 148 may be opaque to electromagnetic radiation within the infrared waveband, such as silicon carbide by way non-limiting example.

The substrate support 150 is arranged within the interior 164 of the chamber body 136 and is supported for rotation R about a rotation axis 174. In this respect it is contemplated that the substrate support 150 be arranged within the divider aperture 170 and coupled to the lift and rotate module 146 through the support member 152 and the shaft member 154. The support member 152 is in turn arranged within the lower chamber 168 of the chamber body 136 and along the rotation axis 174 and is fixed in rotation relative to the substrate support 150. The shaft member 154 is fixed in rotation relative to the support member 152, extends through the lower chamber 168 of the chamber body 136 and a lower wall of the chamber body 136, and is connected to the lift and rotate module 146 to rotate the substrate support 150 about the rotation axis 174. It is contemplated that the support member 152 and/or the shaft member 154 be formed from a transparent material, such as the transparent material 156. It is also contemplated that the substrate support 150 be configured to provide edgewise support to the substrate 2, e.g., such that interior region of the substrate is spaced apart from the substrate support 150 while a peripheral region of the substrate 2 abuts the substrate support 150. Examples of suitable substrate supports include those shown and described in U.S. Patent Application Publication No. 2022/0352006 A1 to Huang et al., filed on Apr. 27, 2022, the contents of which are incorporated herein by reference in their entirety.

The lower heater element array 144 is supported below the chamber body 136 and is configured to communicate electromagnetic radiation within an infrared waveband into the interior 164 of the chamber body 136 to heat the substrate 2 during deposition of the material layer 4 onto the substrate 2. In this respect it is contemplated that the lower heater element array 144 include a plurality of linear heater elements, e.g., linear filament-type linear lamps, each supported below the chamber body 136 and laterally spaced apart from one another below the chamber body 136, the linear heater elements of the lower heater element array 144 each extending longitudinally between the injection end 158 and the exhaust end 160 of the chamber body 136.

The upper heater element array 142 is supported above the chamber body 136, is configured to communicate electromagnetic radiation within the infrared waveband into the interior 164 of the chamber body 136 to heat the substrate 2 during deposition of the material layer 4 onto the substrate 2 and may include a plurality of filament-type lamps, such as linear filament-type lamps. In this respect the plurality of linear filament-type lamps may extend laterally across an upper surface of the chamber body 136 and be longitudinally spaced apart from one another between the injection end 158 and the exhaust end 160 of the chamber body 136. It is also contemplated that the reflector 200 be supported above the chamber body 136, that the upper heater element array 142 separate the reflector 200 from the chamber body 136, and that a pyrometer 176 be supported above the upper heater element array 142, be optically coupled to the interior 164 of the chamber body 136 along an optical axis 178, and be configured to provide a temperature measurement to the controller 108 indicative of temperature of the substrate 2 supported within the interior 164 of the chamber body 136.

As also shown in FIG. 3, the controller 108 includes a device interface 180, a processor 182, a user interface 184, and a memory 186. The device interface 180 connects the processor 182 to the wired or wireless link 114, and therethrough to one or more of the precursor delivery arrangement 102 (shown in FIG. 1), the chamber arrangement 104, and the exhaust source 106 (shown in FIG. 1). The processor 182 is operably connected to the user interface 184 to provide a user output thereto and/or receive therefrom a user input and is disposed in communication with the memory 186. The memory 186 includes a non-transitory machine-readable medium having a plurality of program modules 188 recorded thereon that, when read by the processor 182, cause the processor 182 to execute certain operations. Among the operations are operations of a material layer deposition method 300, as will be described. Although shown and described herein as having a specific arrangement, it is to be understood and appreciated that the controller 108 may have different arrangements (e.g., a distributed computing architecture) in other examples and remain within the scope of present disclosure.

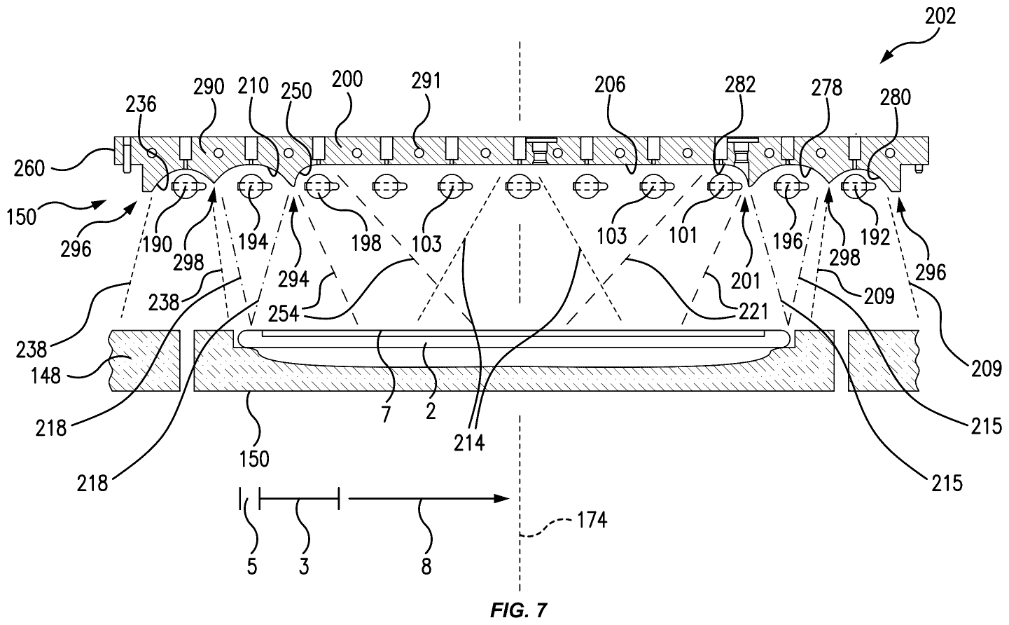

In the illustrated example the substrate 2 has a radially-inner interior surface portion 8 (shown in FIG. 7), a radially-outer peripheral surface portion 3 (shown in FIG. 7), and a bevel 5 (shown in FIG. 7). When seated on the substrate support 150 the rotation axis 174 intersects the radially-inner interior surface portion 8 of the substrate 2 and the radially-inner interior surface portion 8 extends circumferentially about the rotation axis 174. The radially-outer peripheral surface portion 3 extends about the radially-inner interior surface portion 8 and is substantially annular in shape. The bevel 5 extends circumferentially about the radially-outer surface portion 3, is separated from the radially-inner interior surface portion 8 by the radially-outer peripheral surface portion 3 and supports the substrate 2 on the substrate support 150 in an edge-support regime when the substrate 2 is seated on the substrate support 150. In certain examples, the radially-inner interior surface portion 8 may extend from the rotation axis 174 by between about 120 millimeters and about 140 millimeters, for example about 135 millimeters from the rotation axis 174. In accordance with certain examples, the radially-outer peripheral surface portion 3 may extend from about 120 millimeters and about 150 millimeters from the rotation axis 174, for example between about 135 millimeters and about 149 millimeters from the rotation axis 174. The bevel 5 may have a radial width that is between about 1 millimeters and about 3 millimeters and may have a radial width that in about 1 millimeter in certain examples of the present disclosure. It is also contemplated that, in accordance with certain examples, the substrate 2 may include a pattern 7 (shown in FIG. 7) and remain within the scope of the present disclosure.

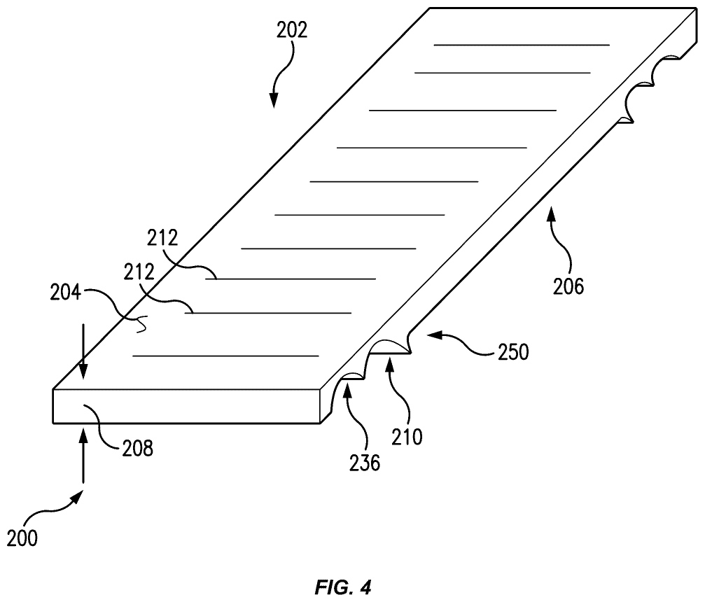

With reference to FIG. 4 and FIGS. 8-11, the reflector 200 is shown in a perspective view. The reflector 200 generally includes a reflector body 202 with a slotted surface 204, a planar surface 206 separated from the slotted surface 204 by a thickness 208 of the reflector body 202, and an ellipsoidal surface 210, also separated from the slotted surface 204 from the slotted surface 204 by the thickness 208 of the reflector body 202 and further longitudinally spaced apart from the planar surface 206 of the reflector body 202. The slotted surface 204 defines therein a plurality of slots 212. The plurality of slots 212 each extend through the thickness 208 of the reflector body 202 and fluidly couple the slotted surface 204 of the reflector body 202 to the planar surface 206 and the ellipsoidal surface 210 of the reflector body 202. It is contemplated that one or more of the plurality of slots 212 fluidly couple the slotted surface 204 to the ellipsoidal surface 210 of the reflector body 202, and that one or more of the plurality of slots 212 fluidly couple the slotted surface 204 of the reflector body 202 to the planar surface 206 of the reflector body 202. As will be appreciated by those of skill in the art in view of the present disclosure, the plurality of slots 212 enable controlling temperature of the chamber body 136 (shown in FIG. 2) and/or the upper heater element array 142 (shown in FIG. 2), by driving a pneumatic coolant flow through the plurality of slots 212 and across the chamber body 136 and/or the upper heater element array 142.

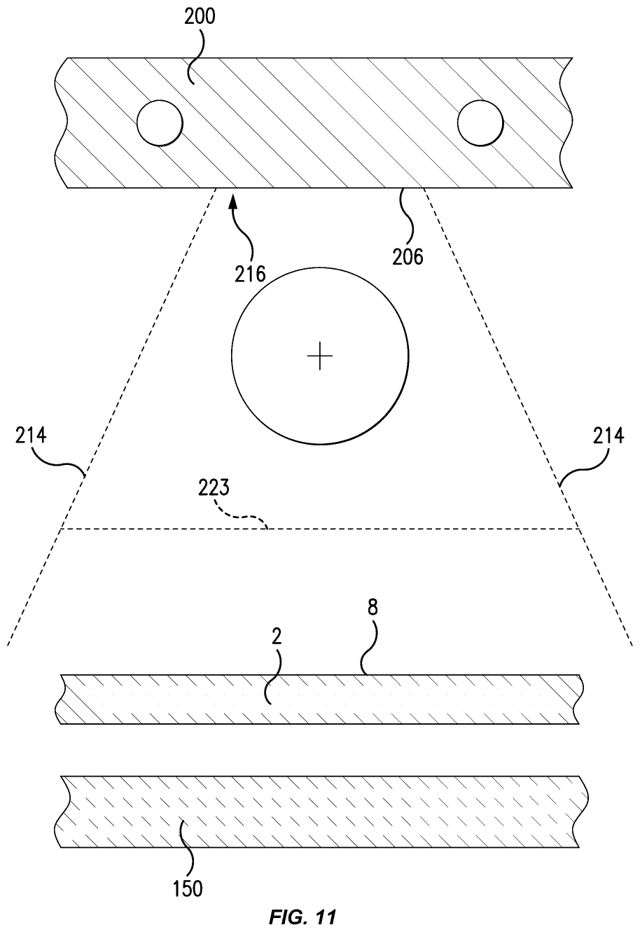

As shown in FIG. 11, the planar surface 206 of the reflector body 202 is substantially planar and is configured to reflect electromagnetic radiation incident upon the planar surface 206 according to a planar surface illumination distribution 214. In this respect it is contemplated that the planar surface 206 define a planar surface profile 216 that longitudinally spans the planar surface 206. The planar surface profile 216 reflects electromagnetic radiation incident along the planar surface 206 according to specular reflection or regular reflection. As will be appreciated by those of skill in the art in view of the present disclosure, specular or regular reflection by the planar surface profile 216 causes rays of electromagnetic radiation incident upon the planar surface 206 to emerge from the planar surface 206 at the same angle to the surface as incident upon the surface but on an opposing side of a planar surface normal in a plane formed by the incident ray and reflected ray, the planar surface 206 limiting heat flux variation within an area illuminated using the planar surface illumination distribution 214.

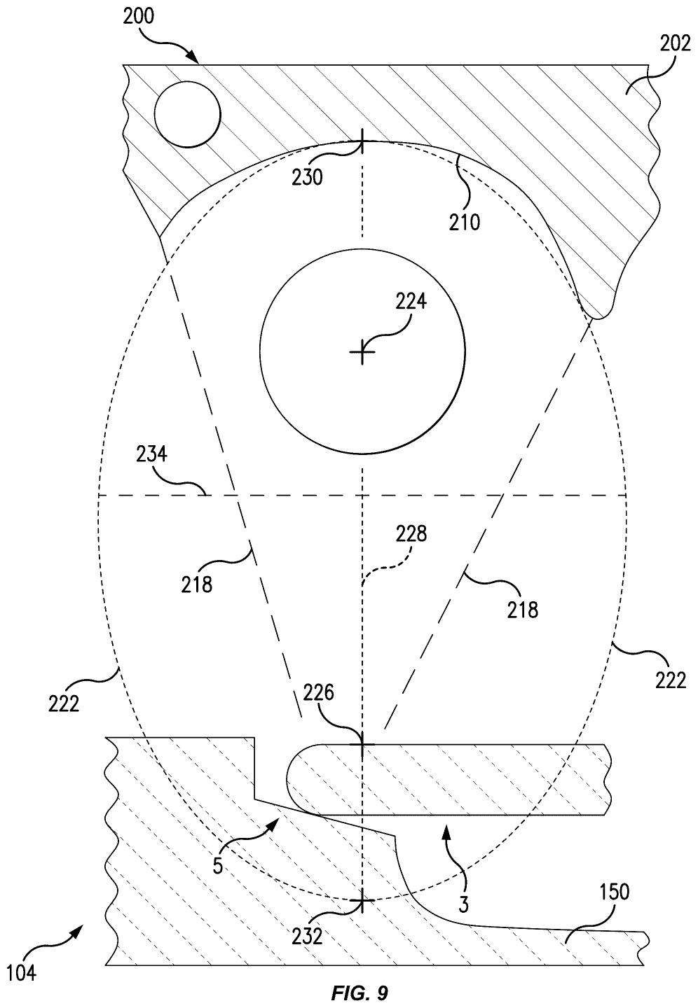

As shown in FIG. 9, the ellipsoidal surface 210 of the reflector body 202 is configured to focus electromagnetic radiation reflected from the ellipsoidal surface 210 at a location overlayed by the ellipsoidal surface 210 according to an ellipsoidal surface illumination distribution 218. In this respect it is contemplated that the ellipsoidal surface 210 define an elliptical profile 222. The elliptical profile 222 is substantially orthogonal relative to the planar surface 206, has a proximal focus 224 and a distal focus 226 arranged along a major axis 228, and further has a proximal vertex 230 and a distal vertex 232 also arranged along the major axis 228, the major axis 228 in turn orthogonal relative to a minor axis 234 of the elliptical profile 222, the minor axis 234 substantially parallel to the planar surface 206 of the reflector body 202. Advantageously, reflecting electromagnetic radiation incident upon the ellipsoidal surface 210 using the elliptical profile 222 according to the ellipsoidal surface illumination distribution 218 concentrates heat flux associated with the reflected illumination within an area overlayed by the ellipsoidal surface 210 of the reflector body 202, increasing temperature variation associated with illumination reflected by the reflector body 202.

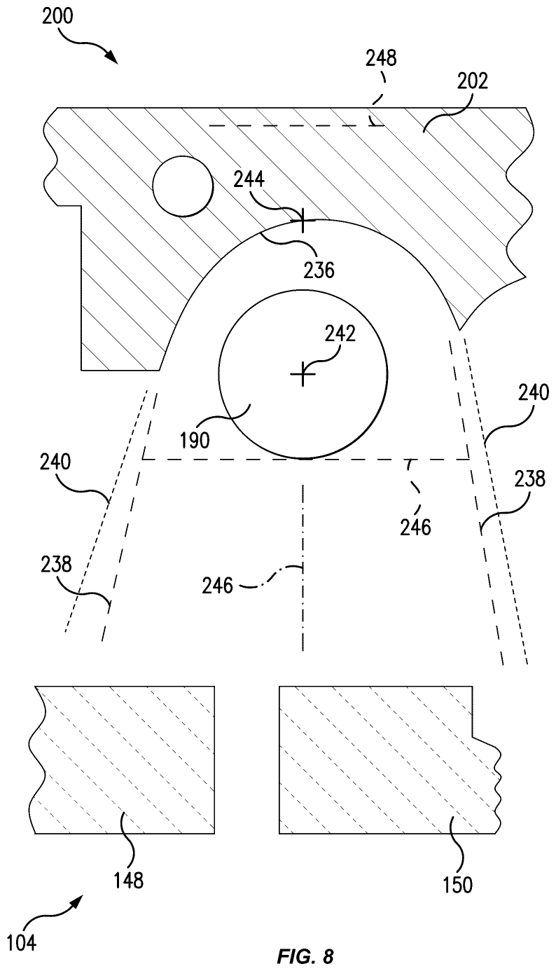

With continuing reference to FIG. 4, it is contemplated that the reflector body 202 may have a paraboloidal surface 236 in certain examples of the present disclosure. As shown in FIG. 8, the paraboloidal surface 236 may be configured to distribute electromagnetic radiation reflected by the paraboloidal surface 236 across an area overlayed by the reflector body 202 and one or more surface longitudinally adjacent to the paraboloidal surface 236 according to a paraboloidal surface illumination distribution 238. In this respect it is contemplated that the paraboloidal surface 236 define a parabolic profile 240. The parabolic profile 240 may be orthogonal relative to the planar surface 206, extend in parallel with the ellipsoidal surface 210 of the reflector body 202, and have a singular focus 242 and a vertex 244. It is contemplated that the singular focus 242 be located between the reflector body 202 and the chamber body 136, that the vertex be located on the paraboloidal surface 236, and the singular focus 242 and the vertex 244 be located on an axis of symmetry 246 defined by the parabolic profile 240 and orthogonal relative to the planar surface 206. It is contemplated that the parabolic profile 240 include a locus of points equidistant from the axis of symmetry 246 and a directrix 248 of the parabolic profile 240, the directrix 248 substantially parallel to the planar surface 206. As will be appreciated by those of skill in the art in view of the present disclosure, the paraboloidal surface illumination distribution 238 distributes electromagnetic reflected by the paraboloidal surface 236 across an area greater than that overlayed by the paraboloidal surface 236, reducing average heat flux in the area overlayed by the paraboloidal surface 236 relative to areas overlayed by adjacent surfaces of the reflector body 202, increasing temperature difference between the area overlayed by the paraboloidal surface 236 and adjacent areas overlayed by surfaces on the reflector body 202 adjacent to the paraboloidal surface 236.

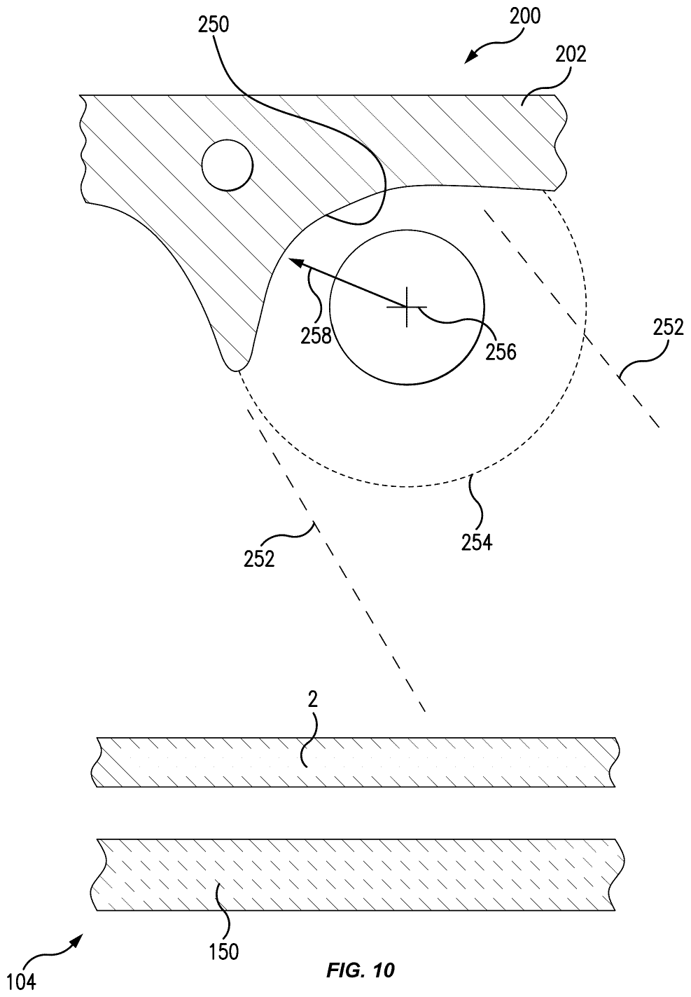

With continuing reference to FIG. 4, the reflector body 202 may have a part-cylindrical surface 250 in certain examples of the present disclosure. The part-cylindrical surface 250 may extend in parallel with the ellipsoidal surface 210 of the reflector body 202. The part-cylindrical surface 250 may further separate the planar surface 206 of the reflector body 202 from the ellipsoidal surface 210 of the reflector body 202. As shown in FIG. 10, the part-cylindrical surface 250 may be configured to longitudinally shift electromagnetic radiation reflected by the part-cylindrical surface 250 to an area longitudinally offset from an area overlayed by the part-cylindrical surface 250 according to a part-cylindrical surface illumination distribution 252. In this respect it is contemplated that the part-cylindrical surface 250 define a part-circular profile 254 with a center 256 and a radius 258, and that a locus of points defining a circumferential segment of the part-circular profile 254 be located on the part-cylindrical surface 250. In further respect, the locus of points defining the circumferential segment of the circular segment of the part-circular profile 254 may have an angular sweep that is between about 20 degrees and about 120 degrees, or between about 45 degrees and about 120 degrees, or even between about 90 degrees and about 90 degrees. Advantageously, shifting reflected electromagnetic radiation with the part-cylindrical surface 250 wherein the part-circular profile 254 has an angular sweep within these ranges can smooth variation in heat flux at within the area overlayed by the planar surface 206, for example at longitudinal edges, when the specular reflection of the planar surface 206 may otherwise cause heat flux variation.

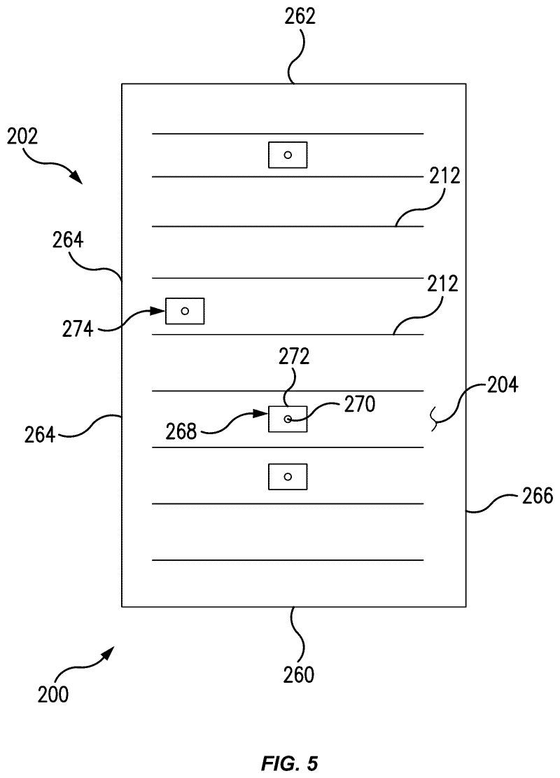

With reference to FIG. 5, the reflector body 202 is shown in a top plan view. In illustrated example the reflector body 202 is configured to be supported above the chamber body 136 and configured to modulate heat flux distribution within the interior 164 (shown in FIG. 3) of the chamber body 136 (shown in FIG. 3) according to position and contour of surfaces opposing the chamber body 136. In this respect it is contemplated that the reflector body 202 be generally rectangular in shape and have an injection edge 260, an exhaust edge 262, a first lateral edge 264, and a second lateral edge 266. The injection edge 260 of the reflector body 202 extends between the first lateral edge 264 and the second lateral edge 266 of the reflector body 202 and may bound the paraboloidal surface 236 of the reflector body 202. The first lateral edge 264 and the second lateral edge 266 extend longitudinally between the injection edge 260 and the exhaust edge 262 of the reflector body 202, are parallel to one another, and are orthogonal relative to the both the injection edge 260 and the exhaust edge 262 of the reflector body 202. It is contemplated that the first lateral edge 264 and the second lateral edge 266 of the reflector body 202 bound the planar surface 206 (shown in FIG. 4) and the ellipsoidal surface 210 (shown in FIG. 4) of the reflector body 202. It is also contemplated that the first lateral edge 264 and the second lateral edge 266 may further bound the paraboloidal surface 236 (shown in FIG. 4) and the part-cylindrical surface 250 (shown in FIG. 4) of the reflector body 202.

The plurality of slots 212 extend laterally across the slotted surface 204 of the reflector body 202 and are laterally offset from both the first lateral edge 264 and the second lateral edge 266 of the reflector body 202. In this respect it is contemplated that the plurality of slots 212 be longitudinally spaced apart from one another between the first lateral edge 264 and the second lateral edge 266 of the reflector body 202 and may be substantially parallel to one another. In further respect, the plurality of slots 212 may be substantially parallel to either (or both) the injection edge 260 and the exhaust edge 262 of the reflector body 202, the plurality of slots 212 may be substantially orthogonal relative to either (or both) the first lateral edge 264 and the second lateral edge 266 of the reflector body 202, and each of the plurality of slots 212 terminate at locations laterally offset from the first lateral edge 264 and the second lateral edge 266. In the illustrated example the reflector body 202 has eleven (11) slots. This is for illustration purposes only and is non-limiting. As will be appreciated by those of skill in the art in view of the present disclosure, the reflector body 202 may have fewer than eleven (11) slots or more than eleven (11) slots and remain within the scope of the present disclosure.

In certain examples the reflector body 202 may include one or temperature sensor seat 268. The one or more temperature sensor seat 268 may include a through-aperture 270 extending through the thickness 208 (shown in FIG. 4) of the reflector body 202 and a fastener pattern 272 defined within the slotted surface 204 of the reflector body 202. The fastener pattern 272 may extend about the through-aperture 270 and be configured to fix a temperature sensor, e.g., the pyrometer 176 (shown in FIG. 2), to the reflector body 202. The through-aperture 270 extends through the reflector body 202 and the thickness 208 of the reflector body 202, and fluidly couples the slotted surface 204 to an opposite surface of the reflector body 202. In this respect it is contemplated that the through-aperture 270 may optically couple the slotted surface 204 of the reflector body 202 to the planar surface 206 (shown in FIG. 4) of the reflector body 202, or optically couple the slotted surface 204 of the reflector body 202 to the ellipsoidal surface 210 (shown in FIG. 4) of the reflector body 202. In certain examples, the reflector body 202 may fluidly separate the through-aperture 270 from the plurality of slots 212. Advantageously, this can improve reliability and/or accuracy of temperature measurements acquired by optical temperature sensors, e.g., the pyrometer, for example by limiting air flow through the through-aperture 270 that could otherwise influence temperature measurements acquired using an optical temperature sensor such as the pyrometer 176 (shown in FIG. 3).

In accordance with certain examples, the one or more temperature sensor seat 268 may be a first temperature sensor seat 268, and the reflector body 202 may have one or more second temperature sensor seat 274. The one or more second temperature sensor seat 274 may be similar to the first temperature sensor seat 268, additionally be laterally and/or longitudinally offset from the first temperature sensor seat 268, and optically couple the slotted surface 204 to either the same surface of reflector body 202 as the first temperature sensor seat 268 or another surface of the reflector body 202 to the slotted surface 204. As will be appreciated by those of skill in the art in view of the present disclosure, this enables acquiring temperature measurements at more than one location below the reflector body 202, for example, at different locations within the chamber body 136 (shown in FIG. 3) and/or from both within the chamber body 136 and the transparent material 156 (shown in FIG. 3) forming the chamber body 136. In the illustrated example the reflector body has four (4) sensor seats, the reflector body 202 thereby configured to support three (3) substrate pyrometers (e.g., ‘wafer’ pyrometers) and a singular chamber pyrometer (e.g., a ‘quartz’ pyrometer). Examples of suitable substrate pyrometers and quartz pyrometers include those shown and described in U.S. Patent Application Publication No. 2022/0301906 A1 to Naik et al., filed on Mar. 17, 2022, the contents of which are incorporated herein by reference in its entirety.

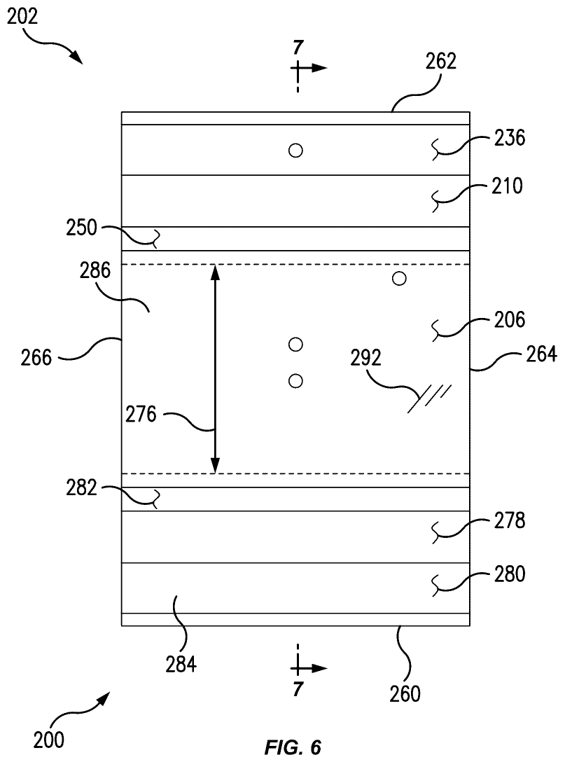

With reference to FIG. 6, the reflector body 202 is shown in a bottom plan view according to an example of the present disclosure. In the illustrated example the planar surface 206 is intermediate the injection edge 260 and the exhaust edge 262 of the reflector body 202. In this respect it is contemplated that the planar surface 206 of the reflector body 202 be longitudinally spaced apart from the injection edge 260 of the reflector body 202, for example by a distance substantially equivalent to greater than a longitudinal span 276 of the ellipsoidal surface 210 of the reflector body 202. In certain examples, the ellipsoidal surface 210 may be a first ellipsoidal surface 210 and the reflector body 202 may include a second ellipsoidal surface 278. The second ellipsoidal surface 278 may be similar to the first ellipsoidal surface 210, additionally be separated from (e.g., longitudinally spaced apart from) the first ellipsoidal surface 210 by the planar surface 206, further separate the planar surface 206 from the exhaust edge 262 of the reflector body 202, and extend in parallel with the first ellipsoidal surface 210 between the first lateral edge 264 and the second lateral edge 266. As shown and described herein the reflector body 202 includes two (2) ellipsoidal surfaces. As will be appreciated by those of skill in the art in view of the present disclosure, the reflector body 202 may have a single ellipsoidal surface or more than two (2) ellipsoidal surfaces and remain within the scope of the present disclosure.

In certain examples, the paraboloidal surface 236 may be a first paraboloidal surface 236 separated from the planar surface 206 by the ellipsoidal surface 210 and the reflector body 202 may have a second paraboloidal surface 280. The second paraboloidal surface 280 may be similar to the first paraboloidal surface 236, additionally separate the second ellipsoidal surface 278 from the exhaust edge 262 of the reflector body 202 and extend in parallel with the first paraboloidal surface 236 between the first lateral edge 264 and the second lateral edge 266 of the reflector body 202. In this respect the second paraboloidal surface 280 may separate both the planar surface 206 and the second ellipsoidal surface 278 from the exhaust edge 262 of the reflector body 202. As shown and described herein the reflector body 202 includes two (2) paraboloidal surfaces. As will be appreciated by those of skill in the art in view of the present disclosure, the reflector body 202 may have a single paraboloidal surface or more than two (2) paraboloidal surfaces and remain within the scope of the present disclosure.

In certain examples, the part-cylindrical surface 250 may be a first part-cylindrical surface 250 and the reflector body 202 may have a second part-cylindrical surface 282. The second part-cylindrical surface 282 may be similar to the first part-cylindrical surface 250, additionally separate the planar surface 206 from second ellipsoidal surface 278 and the exhaust edge 262 of the reflector body 202, and extend in parallel with the first part-cylindrical surface 250 between the first lateral edge 264 and the second lateral edge 266 of the reflector body 202. The second part-cylindrical surface 282 may further separate the planar surface 206 from the second paraboloidal surface 280 of the reflector body 202. As shown and described herein the reflector body 202 includes two (2) part-cylindrical surfaces. As will be appreciated by those of skill in the art in view of the present disclosure, the reflector body 202 may have a single part-cylindrical surface or more than two (2) part-cylindrical surfaces and remain within the scope of the present disclosure.

In certain examples, the reflector body 202 may be monolithically formed and thereby having a monolithic arrangement. In this respect the reflector body 202 may extend continuously and without interruption between the injection edge 260 and the exhaust edge 262 of the reflector body 202. In further respect, the reflector body 202 may further extend continuously and within interruption between the first lateral edge 264 and the second lateral edge 266 of the reflector body 202. As will be appreciated by those of skill in the art in view of the present disclosure, forming the reflector body 202 as a monolithic body may improve temperature control of the chamber body 136 (shown in FIG. 2), for example by limiting coolant leakage through joints defined between segments of the reflector body 202.

In certain examples the reflector body 202 may have segmented and thereby have a segmented arrangement. In this respect the reflector body 202 may include a first reflector body segment 284 and at least one second reflector body segment 286 abutting one another at a joint 288. Advantageously, forming the reflector body 202 as a segmented reflector body may simplify service and maintenance of the chamber arrangement 104 (shown in FIG. 1), for example by limiting weight of the reflector body segments and thereby enabling removal and replacement of the reflector body 202 from the chamber arrangement 104 by a single maintainer.

In certain examples the reflector body 202 may be formed from a bulk metallic material 290 (shown in FIG. 7) and have a reflective coating 292. In certain examples the bulk metallic material 290 may include (or consist of or consist essentially of) an aluminum-containing material, such as 6064 aluminum alloy by way non-limiting example. In accordance with certain examples, the bulk metallic material 290 may include (or consist of or consist essentially of) a copper and zinc-containing material, such as red brass or a dezincification-resistant (DZR) brass material. As will be appreciated by those of skill in the art in view of the present disclosure, forming the reflector body 202 from an aluminum-containing material can limit weight and/or cost of the reflector body. As will also be appreciated by those of skill in the art in view of the present disclosure, forming the reflector body 202 from brass limits the tendency of the reflector body to distort when heated, enabling the reflector to be employed in chamber arrangements employed for material layer deposition at high temperature. Advantageously, forming the reflector body 202 from a DZR brass material enables the reflector body to be cooled with a liquid coolant potentially corrosive (e.g., due to zinc leaching) to brass materials, limiting distortion of the reflector body 202 due to heating such as in chamber arrangements employed for material layer deposition at relatively high temperatures (e.g., greater than 800 degrees Celsius). In this respect the reflector body 202 may define therein one or more coolant channel 291 therein. The one or more coolant channel 291 may further laterally span the reflector body 202 and additionally extend between the slotted surface 204 of the reflector body 202 and the ellipsoidal surface 210 of the reflector body 202 to flow a liquid coolant through the reflector body 202.

The reflective coating 292 overlays at least a portion of reflector body 202, such as at least a portion of the bulk metallic material 290 forming the reflector body 202 and may be reflective to electromagnetic radiation within an infrared waveband. In certain examples, the reflective coating 292 may overlay the planar surface 206 and the ellipsoidal surface of the reflector body 202. In accordance with certain examples the reflective coating 292 may overlay the paraboloidal surface 236 and the part-cylindrical surface 250 of the reflector body 202. It is also contemplated that the reflective coating 292 may overlay the second ellipsoidal surface 278, the second paraboloidal surface 280, and/or the second part-cylindrical surface 282. The reflective coating 292 may include (or consist of or consist essentially of) a reflective material, such as silver or gold by way of non-limiting example. Advantageously, reflective materials such as silver and gold may have coefficients of thermal expansion similar enough to the bulk metallic materials described above within temperature ranges under which the reflector body 202 is maintained during operation to limit distortion of the reflective coating 292 due to thermal cycling of the reflector body 202.

With reference to FIGS. 7-11, a portion of the chamber arrangement 104 including the substrate support 150 and the upper heater element array 142 is shown according to an example of the present disclosure. In the illustrated example the reflector body 202 has an inboard rib 294, an outboard rib 296, and an intermediate rib 298. The inboard rib 294 extends laterally between the first lateral edge 264 (shown in FIG. 5) and the second lateral edge 266 (shown in FIG. 5), longitudinally separates the planar surface 206 from the injection edge 260 and is bounded by the part-cylindrical surface 250 and a portion of the ellipsoidal surface 210 of the reflector body 202. In the illustrated example the inboard rib 294 is a first inboard rib 294 and the reflector body 202 has a second inboard rib 201. The second inboard rib 201 is similar to the first inboard rib 294, is additionally be separated from the first inboard rib 294 by the planar surface 206, and further separates the first inboard rib 294 from the exhaust edge 262 of the reflector body 202. Although shown and described herein as having two (2) inboard ribs it is to be understood and appreciated that the reflector body 202 may have a singular inboard rib or more than two (2) inboard ribs and remain within the scope of the present disclosure.

The outboard rib 296 is longitudinally between the inboard rib 294 and the injection edge 260 of the reflector body 202, extends laterally between the first lateral edge 264 and the second lateral edge 266, and is bounded by a portion of the paraboloidal surface 236 and the injection edge 260. In the illustrated example the outboard rib 296 is first outboard rib 296 and the reflector body 202 has a second outboard rib 203. The second outboard rib 203 is similar to the first outboard rib 296, is additionally longitudinally separated from the first inboard rib 294 by the planar surface 206, and further separates the exhaust edge 262 from the planar surface 206 of the reflector body 202. Although shown and described herein as having two (2) outboard ribs it is to be understood and appreciated that the reflector body 202 may have a singular outboard rib or more than two (2) outboard ribs and remain within the scope of the present disclosure.

The intermediate rib 298 is longitudinally intermediate (e.g., between) the inboard rib 294 and the outboard rib 296 and in this respect longitudinally separates the inboard rib 294 from the outboard rib 296. In further respect it is contemplated that the intermediate rib 298 longitudinally separate the inboard rib 294 from the outboard rib 296, extend between the first lateral edge 264 and the second lateral edge 266, and is bounded by longitudinally adjacent portions of the ellipsoidal surface 210 and the paraboloidal surface 236. In the illustrated example the intermediate rib 298 is a first intermediate rib 298 and the reflector body 202 has a second intermediate rib 205. The second intermediate rib 205 is similar to the first intermediate rib 298, is additionally separated from the first intermediate rib 298 by the planar surface 206 and is further bounded by longitudinally adjacent portions of the second ellipsoidal surface 278 and the second paraboloidal surface 280. Although shown and described herein as having two (2) intermediate ribs it is to be understood and appreciated that the reflector body 202 may have a singular intermediate rib or additional intermediate ribs and remain within the scope of the disclosure.

In the illustrated example the upper heater element array 142 includes eleven (11) upper linear lamps extending laterally across an upper wall of the chamber body 136 and longitudinally spaced apart between the injection end 158 and the exhaust end 160 of the chamber body 136. In this respect the upper heater element array 142 includes a first outboard linear lamp 190 and a second outboard linear lamp 192, a first intermediate linear lamp 194 and a second intermediate linear lamp 196, a first inboard linear lamp 198 and second inboard linear lamp 101, and five (5) center linear lamps 103. Although shown and described here as having eleven (11) laterally extending linear lamps in a longitudinally spaced arrangements, it is to be understood and appreciated that the chamber arrangement 104 (shown in FIG. 1) may have a different heater element array arrangement and remain within the scope of the present disclosure.

The first outboard linear lamp 190 is supported above the chamber body 136 (shown in FIG. 3) and between the reflector body 202 and the chamber body 136 at the injection end 158 (shown in FIG. 3) of the chamber body 136. The first outboard linear lamp 190 is further registered to the first paraboloidal surface 236 of the reflector body 202 and arranged along the axis of symmetry 246 defined by the first paraboloidal surface 236 and may laterally overlay the singular focus 242 of parabolic profile 240 defined by the paraboloidal surface 236. As shown in FIG. 8, so positioned, electromagnetic radiation emitted by the first outboard linear lamp 190 emitted in a direction opposite the chamber body 136 is reflected toward the chamber body 136 along the axis of symmetry 246 (shown in FIG. 8) and into the interior 164 (shown in FIG. 3) of the chamber body 136 according to the paraboloidal surface illumination distribution 238. It is contemplated that the reflected electromagnetic radiation illuminate a portion of the substrate support 150 radially outward of the substrate 2 (e.g., a rim portion of the substrate support 150) and a portion of the divider 148 extending about the substrate support 150.

With continuing reference to FIG. 7, the second outboard linear lamp 192 is similar to the first outboard linear lamp 190 and is additionally supported between the second paraboloidal surface 280 and the chamber body 136 at a location proximate the exhaust end 160 (shown in FIG. 3) of the chamber body 136. It is contemplated that the second outboard linear lamp 192 illuminate structure located within the interior 164 of the chamber body 136 using a second paraboloidal surface distribution 209. The illumination may be oriented along and distributed about an axis of symmetry of a second parabolic profile defined by the second paraboloidal surface 280 of the reflector body 202.

The first intermediate linear lamp 194 is supported above the chamber body 136 and between the reflector body 202 and the chamber body 136 between the first outboard linear lamp 190 and the second outboard linear lamp 192. The first intermediate linear lamp 194 is further supported between the first ellipsoidal surface 210 of the reflector body 202 and the upper wall of the chamber body 136 and along the major axis 228 (shown in FIG. 9) of the elliptical profile 222 (shown in FIG. 9) defined by the ellipsoidal surface 210 of the reflector body 202. As shown in FIG. 9, the first intermediate linear lamp 194 may laterally overlay the proximal focus 224 (shown in FIG. 9) of the elliptical profile 222 defined by the ellipsoidal surface 210 of the reflector body 202. The first intermediate linear lamp 194 may further extend in a parallel with the ellipsoidal surface 210 about the proximal focus 224 laterally between the first lateral edge 264 (shown in FIG. 5) and the second lateral edge 266 (shown in FIG. 5) of the reflector body 202. So positioned, electromagnetic radiation emitted by the first intermediate linear lamp 194 emitted in a direction opposite the chamber body 136 is reflected toward the chamber body 136 along the major axis 228 of the elliptical profile 222 and into the interior 164 of the chamber body 136 according to the first ellipsoidal surface illumination distribution 218.

With continuing reference to FIG. 7, the second intermediate linear lamp 196 is similar to the first intermediate linear lamp 194 and is additionally supported between the second ellipsoidal surface 278 and the chamber body 136 (shown in FIG. 3) at a location proximate the second outboard linear lamp 192. It is contemplated that second intermediate linear lamp 196 illuminate structure located within the interior 164 of the chamber body 136 using a second ellipsoidal surface distribution 215. In this respect it is contemplated that the second ellipsoidal surface 278 also illuminate the radially-outer peripheral surface portion 3 along a second major axis 217 of a second elliptical profile 219 defined by the second ellipsoidal surface 278 of the reflector body 202. As will be appreciated by those of skill in the art in view of the present disclosure, this can increase the tunability provided by the first ellipsoidal surface 210 of the reflector body 202. As will also be appreciated by those of skill in the art in view of the present disclosure, this can amplify the tunability provided by the first ellipsoidal surface 210 in examples where one or more of the exterior ribs 162 (shown in FIG. 3) of the chamber body 136 shade the substrate 2 from electromagnetic radiation reflected by the first ellipsoidal surface 210.

The first inboard linear lamp 198 is supported above the chamber body 136 and between the reflector body 202 and the chamber body 136 (shown in FIG. 3) at a location longitudinally between the first intermediate linear lamp 194 and the exhaust end 160 (shown in FIG. 3) of the chamber body 136. The first inboard linear lamp 198 is further underlies the first part-cylindrical surface 250 of the reflector body 202, extends in parallel with the first part-cylindrical surface 250 of the reflector body 202. As shown in FIG. 10, the first inboard linear lamp 198 may laterally overlap (e.g., be concentric with) the center 256 of the first part-circular profile 254 defined by the first part-cylindrical surface 250 of the reflector body 202. So positioned, electromagnetic radiation emitted by the first inboard linear lamp 198 in a direction opposite the chamber body 136 is reflected by first part-cylindrical surface 250 toward the chamber body 136 into the interior 164 (shown in FIG. 3) of the chamber body 136 and shifted toward the rotation axis 174 according to the first part-cylindrical surface illumination distribution 252.

With continuing reference to FIG. 7, the second inboard linear lamp 101 is similar to the first inboard linear lamp 198 and is additionally supported between the second part-cylindrical surface 282 and the chamber body 136 (shown in FIG. 3) at a location between the first inboard linear lamp 198 and the second intermediate linear lamp 196. It is contemplated that the second inboard linear lamp 101 illuminate structure (e.g., the radially-inner interior surface portion 8 of the substrate 2) located within the interior 164 (shown in FIG. 3) of the chamber body 136 shifted toward the rotation axis 174. It is further contemplated that the second part-cylindrical surface 282 illuminate the structure using a second part-cylindrical surface illumination distribution 221 defined by the second part-cylindrical surface 282 of the reflector body 202. As will be appreciated by those of skill in the art in view of the present disclosure, this provides further compensation for variation in reflected electromagnetic radiation from the planar surface 206 of the reflector body 202. The second part-cylindrical surface illumination distribution 221 may further compensate for shading of electromagnetic radiation reflected from the planar surface 206 by the plurality of exterior ribs 162 (shown in FIG. 3), such as when the plurality of exterior ribs 162 have different spacing on longitudinally opposite sides of the rotation axis 174 relative to one another.

The center linear lamps 103 are supported between the planar surface 206 of the reflector body 202 and the chamber body 136 (shown in FIG. 3) and are longitudinally distributed between the first inboard linear lamp 198 and the second inboard linear lamp 101. The center linear lamps 103 are further distributed on longitudinally opposite sides of the rotation axis 174 between the injection end 158 (shown in FIG. 3) of the chamber body 136 and the exhaust end 160 (shown in FIG. 3) of the chamber body 136. As shown in FIG. 11, the planar surface 206 thereby illuminates structure (e.g., the radially-inner interior surface portion 8 of the substrate 2) within the interior 164 (shown in FIG. 3) according to a planar surface illumination distribution 214 associated with each of the plurality of center linear lamps 103 according to an interleaved illumination distribution 223 associated with the plurality of center linear lamps 103. As will be appreciated by those of skill in the art in view of the present disclosure, this can limit variation in heat flux in the structure illuminated by electromagnetic radiation generated by the plurality of center linear lamps 103 and reflected into the interior 164 of the chamber body 136 by the planar surface 206. As will also be appreciated by those of skill in the art in view of the present disclosure, variation at the longitudinally opposite edges of the interleaved illumination distribution 223 may be limited by the first part-cylindrical surface illumination distribution 252 (shown in FIG. 7) and the second part-cylindrical surface illumination distribution 221 (shown in FIG. 7).

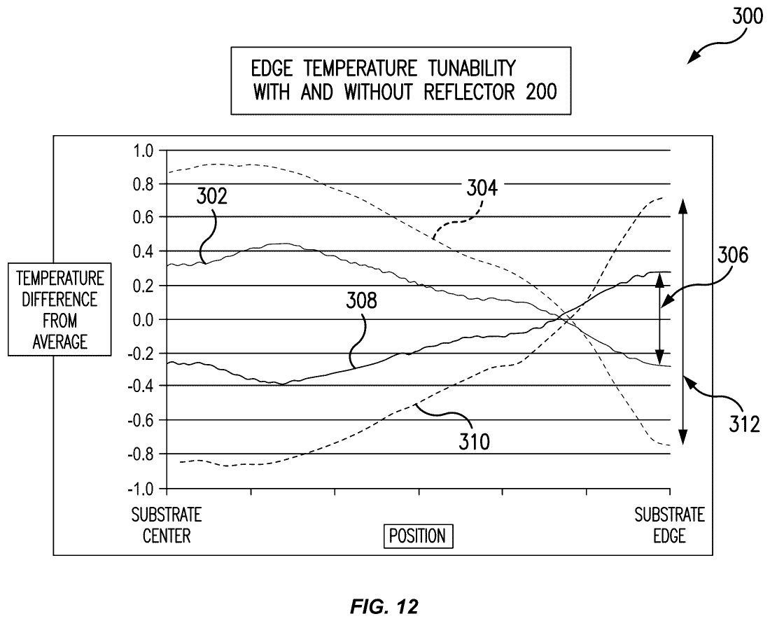

With reference to FIG. 12, cross-substrate temperature tunability within at range 80% to 120% of nominal power applied to the first intermediate linear lamp 194 and the second intermediate linear lamp 196 is comparatively shown for the chamber arrangement 104 (shown in FIG. 1) in comparison to a chamber arrangement not including reflector 200 (shown in FIG. 1) is shown with a chart 300. As shown with trace 302 and trace 304, temperature within at a peripheral surface region of a substrate may change within a range of about 0.6 degrees Celsius relative to the interior surface region of the substrate in chamber arrangements not including the reflector 200 when power applied to the first intermediate linear lamp 194 and the second intermediate linear lamp 196 is throttled between about 80% and about 120% of nominal power, as shown with arrow 306. In contrast, as shown with trace 308 and trace 310 with arrow 312, temperature at the peripheral surface region of the substrate 2 (shown in FIG. 1) at the bevel can be throttled within a range of about 1.6 degrees Celsius relative to the interior surface region of the substrate 2 when power applied to the first intermediate linear lamp 194 and the second intermediate linear lamp 196 is throttled between about 80% and about 120% of nominal power. Advantageously, tunability within these ranges imparts into the chamber arrangement 104 a capability to compensate for greater amounts of edge roll-up and edge roll-down than otherwise possible, such as deposition processes where material layers are deposited onto patterned substrates having high emissivity, than possible with chamber arrangements not including the reflector 200. For example, magnitude of edge roll-up or edge roll-down in the material layer 4 (shown in FIG. 1) overlaying the radially-outer peripheral surface portion 5 (shown in FIG. 7) of the substrate 2 (shown in FIG. 1) may be tuned to less than one-half that of roll-up and roll-down deposited in a chamber arrangement not including the reflector 200 (shown in FIG. 1).

With reference to FIG. 13, the material layer deposition method 400 is shown. The method 400 includes, at a semiconductor processing system having a reflector as described above, positioning a substrate at a distal focus defined by the elliptical profile of the reflector body, e.g., the substrate 2 (shown in FIG. 1) at the distal focus 226 (shown in FIG. 9) of the elliptical profile 222 (shown in FIG. 9) defined by the ellipsoidal surface 210 (shown in FIG. 4) of the reflector body 202 (shown in FIG. 4), as shown with box 410. The method 400 also includes heating the substrate using electromagnetic radiation emitted toward the substrate by one or more linear lamp supported at a proximal focus of the elliptical profile of the reflector body, e.g., the proximal focus 224 (shown in FIG. 9) of the elliptical profile defined by the ellipsoidal surface, as shown with box 520. The method 400 further includes further heating the substrate by reflecting electromagnetic radiation emitted in a direction opposite the substrate by the one or more linear lamp toward the distal focus using the ellipsoidal surface of the reflector body, and depositing a silicon-containing material layer, e.g., the material layer 4 (shown in FIG. 1), onto the substrate using an epitaxial deposition technique, as shown with box 430 and box 440. It is contemplated that the ellipsoidal surface concentrate heat flux at the distal focus of the elliptical profile using the electromagnetic radiation reflected by the ellipsoidal surface in the ellipsoidal surface illumination distribution, and that heat flux at the distal focus of the elliptical profile limits cross-substrate variation within the silicon material deposited onto the substrate using the epitaxial deposition technique by increasing tunability of substrate temperature at the radially-outer peripheral surface portion of the substrate using power applied to the one or more linear lamp, as shown with box 442 and box 444.

In certain examples reflector body may have a paraboloidal surface, e.g., the paraboloidal surface 236 (shown in FIG. 4), and the method 400 may also include distributing electromagnetic radiation reflected by the paraboloidal surface onto structure located radially outward of the substrate, as shown with box 450. The paraboloidal surface may reflect electromagnetic radiation incident upon the paraboloidal surface according to a parabolic surface illumination distribution, e.g., the paraboloidal surface illumination distribution 238 (shown in FIG. 7) and distribute heat flux radially outward of the ellipsoidal surface of the reflector body, as shown with box 452. It is contemplated that the electromagnetic radiation reflected by the paraboloidal surface further limit variation within the material layer deposition onto the substrate, for example, by conducting heat distributed onto a surface portion of a substrate support seating the substrate radially outward of the substrate using the paraboloidal surface illumination distribution into a contact surface seating the substrate, as shown with box 454.

In certain examples the reflector body may include a part-cylindrical surface, e.g., the part-cylindrical surface 250 (shown in FIG. 4), and that the cylindrical surface may distribute electromagnetic radiation reflected by the cylindrical surface to an interior surface region of the substrate overlayed by the planar surface of the reflector body, as shown with box 460. The part-cylindrical surface may reflect electromagnetic radiation according to a part-cylindrical surface illumination distribution, e.g., using the part-cylindrical surface illumination distribution 252 (shown in FIG. 7), radially inward of the ellipsoidal surface of the reflector, as shown with box 462. The part-cylindrical surface may further limit cross-substrate variation within the material layer deposited onto the substrate, for example, by compensating for heat flux variation association with a planar surface illumination distribution associated with specular or regular reflection of electromagnetic radiation reflected from a planar surface, e.g., the planar surface illumination distribution 214 (shown in FIG. 7), as shown with box 464.

In certain examples the reflector body may have a planar surface, e.g., the planar surface 206 (shown in FIG. 4), and that the method 400 may include further heating a radially-inner interior surface portion of the substrate using electromagnetic radiation reflected from the planar surface of the reflector body, as also shown with box 440. The planar surface may reflect electromagnetic radiation incident upon the planar surface according to the planar surface illumination distribution, and the planar surface illumination distribution may limit material layer variation within the material layer deposited onto a radially-inner interior surface portion of the substrate seated on the substrate support, as further shown with box 440.

Cross-substrate temperature variation may be controlled in single-wafer crossflow chamber arrangements by varying power applied to the lamps supported outside of the chamber arrangement and employed to heat the substrate seated within the chamber arrangement. For example, in substrates exhibiting relatively layer center-to-edge temperature variation (e.g., patterned substrates exhibiting high emissivity relative to blanket substrates), power applied to lamps overlaying the substrate periphery may be increased relative power applied to lamps overlaying the interior surface region of the substrate. Such edge power biasing techniques can, within the physical constraints of the lamp design and lamp power supply system, limit center-to-edge variation within the material layer deposited onto the substrate otherwise associated with center-to-edge temperature variation characteristic of the substrate. However, in certain substrates, emissivity of the substrate may be such that the center-to-edge temperature variation characteristic of the substrate exceeds the capability of the compensation through lamp power biasing.

In examples described herein, reflectors are provided that concentrate reflected electromagnetic radiation at the peripheral surface portion of the substrate, increasing tunability of temperature compensation through lamp power adjustments otherwise available at peripheral surface portion of the substrate. In this respect a reflector having an ellipsoidal surface overlying the peripheral surface portion may be employed to concentrate reflected electromagnetic radiation on the peripheral surface portion of the substrate. The reflected electromagnetic radiation may be concentrated at surface location overlaying a contact location between the substrate and the substrate support opposite the peripheral surface portion of the substrate, locally increasing heat flux and attenuating the heat otherwise characteristic of the substrate. Where the substrate exhibits relatively low emissivity (e.g., an unpatterned blanket substrate), the concentration of reflected electromagnetic radiation at the peripheral surface portion increases the ability to compensate for material layer thickness roll-up (local thickening) on the peripheral surface portion of the substrate relative to the interior surface portion of the substrate using lamp power adjustments. Where the substrate exhibits relatively high emissivity (e.g., a patterned substrate), the concentration of reflected electromagnetic radiation at the substrate peripheral surface portion increases the ability to compensate for material layer thickness roll-down (local thickening) on the peripheral surface portion of the substrate relative to the interior surface portion of the substrate using lamp power adjustments. In either process, properties of the material layer overlaying the substrate peripheral surface portion may more closely resemble those of within the material layer overlaying the substrate surface interior portion, improving performance of semiconductor devices formed using the material layer overlaying the peripheral surface portion of the substrate.

In certain examples reflectors described herein the reflector may have a paraboloidal surface. The paraboloidal surface may be radially outward of the substrate and overlay a portion of the substrate support radially outward the on the substrate bevel to distribute reflected electromagnetic radiation across the portion of the substrate support radially outward of the substrate bevel. This further increases tunability of lamps overlaying the substrate peripheral surface portion using lamps overlaying the substrate support radially outward of the substrate through conductive heating of the substrate support contact surface seating the substrate using electromagnetic radiation reflected by the paraboloidal surface. In accordance with certain examples, reflectors described herein may have a part-cylindrical surface. The part cylindrical surface may be radially inward of the ellipsoidal surface, overlay the interior surface portion of the substrate, and shift reflected electromagnetic radiation reflected by the part-cylindrical surface in a direction opposite the ellipsoidal surface, compensating for heat flux variation across the interior surface portion of the substrate associated with specular reflection of electromagnetic radiation reflected by a planar surface of the reflector separated from the ellipsoidal surface by the part-cylindrical surface of the reflector.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A reflector, comprising:
a reflector body having:
a slotted surface;
a planar surface opposite the slotted surface and separated from the slotted surface by a thickness of the reflector body; and
an ellipsoidal surface offset from the planar surface and opposite the slotted surface, the ellipsoidal surface separated from the slotted surface by the thickness of the reflector body,
wherein the ellipsoidal surface defines an elliptical profile that is orthogonal relative to the planar surface,
wherein the ellipsoidal surface spans the slotted surface of the reflector body, and
wherein the ellipsoidal surface concentrates heat flux at a distal focus of the elliptical profile using electromagnetic radiation reflected by the ellipsoidal surface of the reflector body.

2. The reflector of claim 1, wherein the ellipsoidal surface is a first ellipsoidal surface and the reflector body has a second ellipsoidal surface separated from the slotted surface by the thickness of the reflector body, wherein the second ellipsoidal surface extends in parallel with the first ellipsoidal surface, and wherein the second ellipsoidal surface separated from the first ellipsoidal surface by the planar surface.

3. The reflector of claim 1, wherein the reflector body has a paraboloidal surface defining a parabolic profile that is orthogonal relative to the planar surface, the paraboloidal surface extending in parallel with the ellipsoidal surface of the reflector body.

4. The reflector of claim 3, wherein the ellipsoidal surface separates the paraboloidal surface of the reflector body from the planar surface of the reflector body.

5. The reflector of claim 3, wherein the paraboloidal surface of the reflector body is separated from the ellipsoidal surface of the reflector body by the planar surface of the reflector body.

6. The reflector of claim 1, wherein the reflector body has a part-cylindrical surface defining a part-circular profile, the part-circular profile orthogonal relative to the planar surface, the part-cylindrical surface extending in parallel with the ellipsoidal surface of the reflector body.

7. The reflector of claim 6, wherein the part-cylindrical surface of the reflector body separates the ellipsoidal surface of the reflector body from the planar surface of the reflector body.

8. The reflector of claim 6, wherein the part-cylindrical surface of the reflector body is separated from the ellipsoidal surface by the planar surface of the reflector body.

9. The reflector of claim 1, wherein the reflector body has an inboard rib portion, the inboard rib portion separating the planar surface of the reflector body from the ellipsoidal surface of the reflector body, the inboard rib portion having a part-cylindrical surface defining a part-circular profile that is orthogonal relative to the planar surface and facing the planar surface.

10. The reflector of claim 1, wherein the reflector body has an intermediate rib portion, the intermediate rib portion separated from the planar surface by the ellipsoidal surface of the reflector body, the intermediate rib portion having a paraboloidal surface defining a parabolic profile, the parabolic profile orthogonal relative to the planar surface of the reflector body.

11. The reflector of claim 1, wherein the reflector body has an outboard rib portion, the outboard rib portion separated from the planar surface by the ellipsoidal surface of the reflector body, the outboard rib portion having a paraboloidal surface and an edge surface, the paraboloidal surface defining a parabolic profile that is orthogonal relative to the planar surface, the edge surface orthogonal relative to the planar surface.

12. The reflector of claim 1, wherein the reflector body is formed from a bulk metallic material, and further comprising a gold coating conformally deposited onto both the planar surface and the ellipsoidal surface of the reflector body.

13. The reflector of claim 1, wherein the slotted surface defines a plurality of slots therein that extend in parallel with the ellipsoidal surface of the reflector body, the plurality of slots fluidly coupling the slotted surface with the planar surface and the ellipsoidal surface of the reflector body, and wherein the thickness of the reflector body defines a coolant channel extending between the slotted surface and the ellipsoidal surface of the reflector body.

14. The reflector body of claim 1, wherein the reflector body has a monolithic arrangement, or wherein the reflector body has a segmented arrangement including a first body segment and at least one second segment, the planar surface defined on the first body segment, the ellipsoidal surface defined on the at least one second body segment, the second body segment abutting the first body segment at joint spanning the reflector body.

15. A semiconductor processing system, comprising:
a chamber body formed from a transmissive material;
a substrate support arranged within the chamber body;
a reflector as recited in claim 1 supported above the chamber body; and
a lamp array including a plurality of linear lamps supported between the reflector and the chamber body,
wherein a first of the plurality of linear lamps extends about a proximal focus of the elliptical profile defined by the ellipsoidal surface of the reflector body, and
wherein a second of the plurality of linear lamps separate the planar surface of the reflector body from the chamber body and is parallel to the first of the plurality of linear lamps.

16. The semiconductor processing system of claim 15, wherein a distal focus of the elliptical profile intersects a surface of a substrate seated on the substrate support.

17. The semiconductor processing system of claim 15, wherein the chamber body has a plurality of external ribs extending in parallel with the ellipsoidal surface, and wherein the first of the plurality of linear lamps overlays one of the plurality of external ribs.

18. The semiconductor processing system of claim 15, wherein the chamber body has a plurality of external ribs extending in parallel with the ellipsoidal surface, and wherein the first of the plurality of linear lamps is between two of the plurality of external ribs.

19. The semiconductor processing system of claim 15, wherein the substrate support is supported for rotation within the chamber body for rotation about a rotation axis, wherein the distal focus is offset from the rotation axis by between about 135 millimeters and about 155 millimeters.

20. A material layer deposition method, comprising:
at a semiconductor processing system including a reflection with a reflector body having a slotted surface, a planar surface opposite the slotted surface and separated from the slotted surface by a thickness of the reflector body, and an ellipsoidal surface offset from the planar surface and opposite the slotted surface, the ellipsoidal surface separated from the slotted surface by the thickness of the reflector body, the ellipsoidal surface defining an elliptical profile orthogonal relative to the planar surface, the ellipsoidal surface spanning the slotted surface of the reflector body,
positioning a substrate at a distal focus of the elliptical profile defined by the ellipsoidal surface of the reflector body;
heating the substrate using electromagnetic radiation emitted toward the substrate by a lamp supported at a proximal focus of the elliptical profile of the reflector body;
further heating the substrate by reflecting electromagnetic radiation emitted in a direction opposite the substrate toward the distal focus using the ellipsoidal surface of the reflector body;
depositing a silicon-containing material layer onto the substrate using an epitaxial deposition technique;
whereby the ellipsoidal surface concentrates heat flux at the distal focus of the elliptical profile using electromagnetic radiation reflected by the ellipsoidal surface; and
whereby heat flux concentrated at the distal focus of the elliptical profile limits cross-substrate variation within the silicon-containing material layer deposited onto the substrate using the epitaxial deposition technique.
